(19) United States
(12) Patent Application Publication
(10) Pub. No.: US 2026/0013162 A1
(43) Pub. Date: Jan. 8, 2026

(54) SEMICONDUCTOR DEVICE AND METHOD FOR MANUFACTURING THE SAME

(71) Applicants: Kabushiki Kaisha Toshiba, Tokyo (JP); Toshiba Electronic Devices & Storage Corporation, Tokyo (JP)

(72) Inventors: Motoya KISHIDA, Kanazawa Ishikawa (JP); Hidenobu KOJIMA, Kanazawa Ishikawa (JP)

(21) Appl. No.: 19/067,396

(22) Filed: Feb. 28, 2025

(30) Foreign Application Priority Data
Jul. 8, 2024 (JP) 2024-109740

(51) Int. Cl. H10D 12/00; H10D 12/01; H10D 62/10; H10D 64/23

(52) U.S. Cl. CPC H10D 12/481; H10D 12/038; H10D 12/415; H10D 62/107; H10D 64/232; H10D 62/126

(57) ABSTRACT

A semiconductor device includes a first electrode; a first semiconductor region of a first conductivity type on the first electrode and including a first region and a second region positioned around the first region; a second semiconductor region of a second conductivity type on the first region; a third semiconductor region of the first conductivity type on the second semiconductor region; a gate electrode facing the second semiconductor region via a gate insulating layer; a fourth semiconductor region of the second conductivity type on the second region and spaced apart from the second semiconductor region; a second electrode provided on the third semiconductor region via a first contact; a third electrode provided on the fourth semiconductor region via a second contact. The first and second contacts each include a titanium-containing layer, a titanium nitride-containing layer on the titanium-containing layer, and a tungsten-containing layer on the titanium nitride-containing layer.

### CROSS-REFERENCE TO RELATED APPLICATION(S)

This application is based upon and claims the benefit of priority from Japanese Patent Application No. 2024-109740, filed on Jul. 8, 2024, the entire contents of which are incorporated herein by reference.

### FIELD

Embodiments described herein relate generally to a semiconductor device and a method for manufacturing the semiconductor device.

### BACKGROUND

Insulated-gate bipolar transistors (IGBTs) and Metal-oxide semiconductor field-effect transistors (MOSFETs) are semiconductor devices used for applications such as power conversion. These semiconductor devices include semiconductor regions, electrodes, and contacts connecting the semiconductor regions and electrodes. There is a need for technology that can suppress the reaction between the semiconductor material of the semiconductor region and the metal material of the electrode.

### BRIEF DESCRIPTION OF THE DRAWINGS

FIG. 1 is a plan view showing a semiconductor device according to an embodiment.

FIG. 2 is a cross-sectional view taken along line II-II of FIG. 1.

FIG. 3 is a cross-sectional view taken along line III-III of FIG. 1.

FIG. 4 is a cross-sectional view taken along line IV-IV of FIG. 1.

FIG. 5 is an enlarged cross-sectional view of a part of FIG. 2.

FIG. 6 is an enlarged cross-sectional view of a part of FIG. 3.

FIG. 7 is an enlarged cross-sectional view of a part of FIG. 4.

FIGS. 8A to 8D, 9A to 9D, and 10A to 10D are cross-sectional views showing a method of manufacturing a semiconductor device according to an embodiment.

FIGS. 11A to 11D are cross-sectional views showing a manufacturing method according to a first reference example.

FIGS. 12A to 12D and 13A to 13B are cross-sectional views showing a manufacturing method according to a second reference example.

FIG. 14 is a cross-sectional view showing another example of a second contact.

FIGS. 15A to 15D and FIGS. 16A to 16B are cross-sectional views showing a method of manufacturing a semiconductor device according to an embodiment.

FIG. 17 is a perspective cross-sectional view showing a part of a semiconductor device according to a modified example of the embodiment.

FIG. 18 is a perspective cross-sectional view showing another part of a semiconductor device according to a modified example of the embodiment.

### DETAILED DESCRIPTION

The following describes each embodiment of the present invention with reference to the drawings. The drawings are schematic or conceptual, and the relationship between the thickness and width of each part, the size ratio between parts, etc., are not necessarily the same as actual ones. Even if the same part is represented in different figures, the dimensions and ratios may differ in the different figures. In this specification and the drawings, elements already described are denoted by the same reference numerals, and detailed descriptions are appropriately omitted.

In the following description and drawings, the notations n+, n, n− and p+, p, p− indicate the relative levels of impurity concentration. That is, the notation with “+” indicates a relatively higher impurity concentration than the notation without “+” or “−”, and the notation with “−” indicates a relatively lower impurity concentration than the notation without “+” or “−”. These notations represent the relative levels of net impurity concentration after compensation when both p type and n type impurities are included in the respective regions.

Each embodiment described below may be implemented by reversing the p type and n type of each semiconductor region.

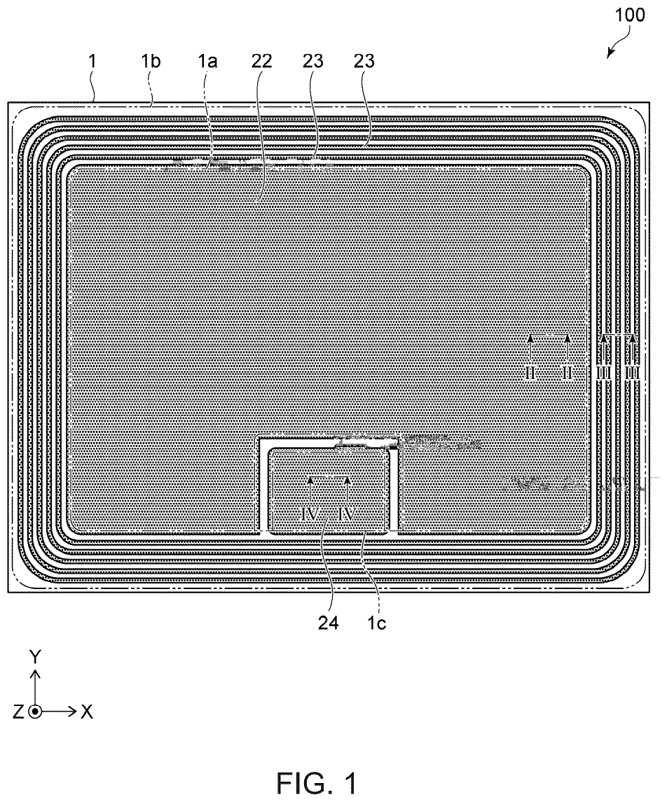

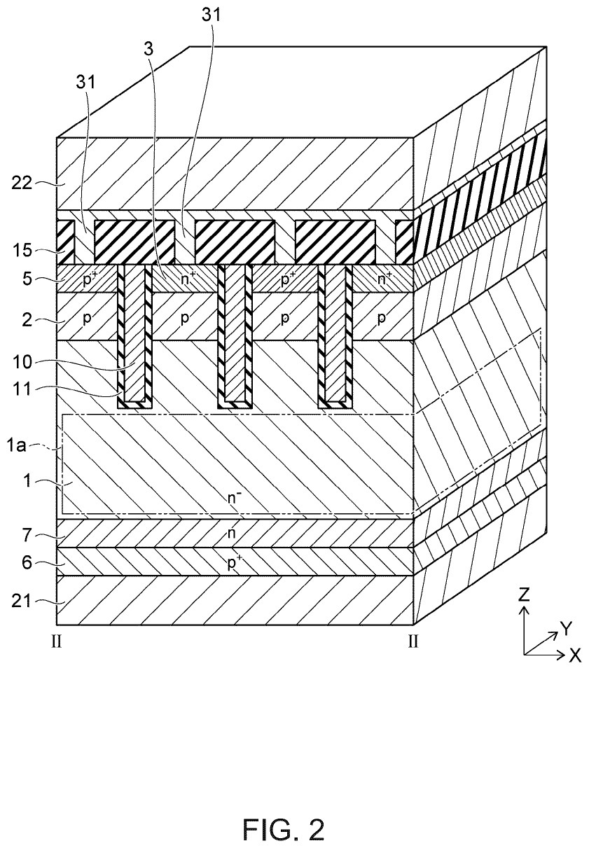

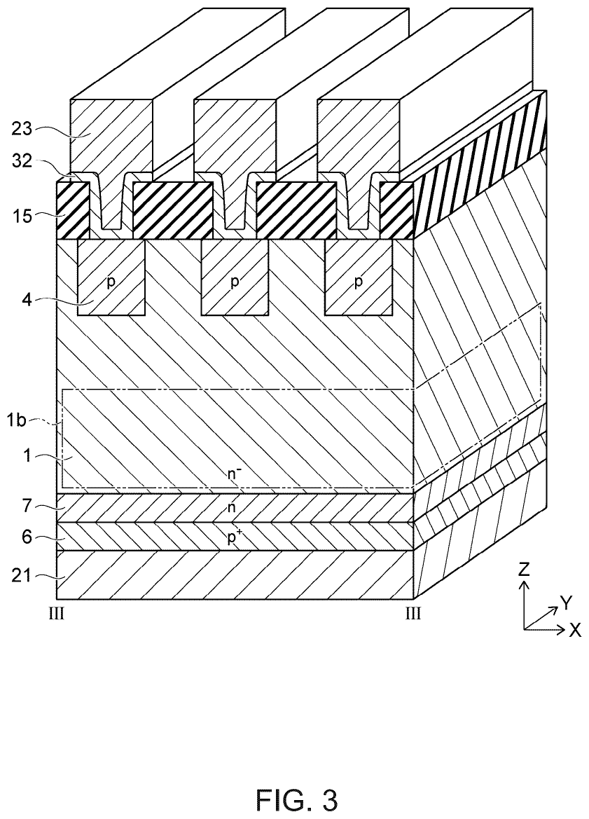

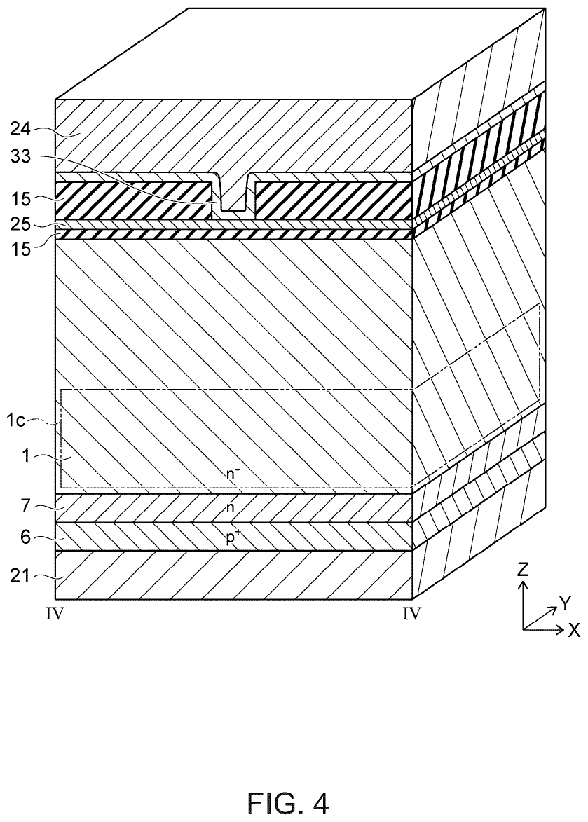

FIG. 1 shows a plan view of the semiconductor device according to the embodiment. FIG. 2 is a cross-sectional view along line II-II of FIG. 1. FIG. 3 is a cross-sectional view along line III-III of FIG. 1. FIG. 4 is a cross-sectional view along line IV-IV of FIG. 1.

The semiconductor device 100 according to the embodiment is an IGBT. As shown in FIGS. 1 to 4, the semiconductor device 100 includes an n− type (first conductivity type) semiconductor region 1 (first semiconductor region), a p type (second conductivity type) base region 2 (second semiconductor region), an n+ type source region 3 (third semiconductor region), a p type guard ring region 4 (fourth semiconductor region), a p+ type contact region 5, a p+ type collector region 6, an n type buffer region 7, a gate electrode 10, a gate insulating layer 11, an insulating layer 15, a lower electrode 21 (first electrode), an upper electrode 22 (second electrode), a guard ring electrode 23 (third electrode), a gate pad 24, a gate wiring 25, a first contact 31, a second contact 32, and a third contact 33.

In the description of the embodiment, an XYZ orthogonal coordinate system is used. The direction from the lower electrode 21 to the first region 1a of the n− type semiconductor region 1 is defined as the Z direction (first direction). The two directions perpendicular to the Z direction and orthogonal to each other are defined as the X direction (second direction) and the Y direction (third direction). For the sake of explanation, the direction from the lower electrode 21 to the first region 1a is referred to as “up,” and the opposite direction is referred to as “down.” These directions are based on the relative positional relationship between the lower electrode 21 and the first region 1a and are independent of the direction of gravity.

As shown in FIG. 1, the upper surface of the semiconductor device 100 is provided with the upper electrode 22, the guard ring electrode 23, and the gate pad 24. The upper electrode 22, the guard ring electrode 23, and the gate pad 24 are separated from each other. The guard ring electrode 23 is positioned around the upper electrode 22 and the gate pad 24 along the XY plane.

As shown in FIGS. 2 to 4, the lower surface of the semiconductor device 100 is provided with the lower electrode 21. The p+ type collector region 6 is provided on the lower electrode 21 and is electrically connected to the lower electrode 21. The n type buffer region 7 is provided on the p+ type collector region 6.

The n− type semiconductor region 1 is provided on the n type buffer region 7. The n type impurity concentration in the n− type semiconductor region 1 is lower than the n type impurity concentration in the n type buffer region 7. As shown in FIGS. 1 to 4, the n− type semiconductor region 1 includes a first region 1a, a second region 1b, and a third region 1c. The second region 1b is positioned around the first region 1a in the XY plane. The first region 1a is located in the cell region. The cell region is the region where the main current flows during the operation of the semiconductor device 100. The second region 1b is located in the termination region. The termination region is the region where the depletion layer spreads toward the outer periphery of the semiconductor device 100 during the application of high voltage. The third region 1c is provided between a part of the first region 1a and a part of the second region 1b and is located below the gate pad 24.

As shown in FIG. 2, the p type base region 2 is provided above the first region 1a. The n+ type source region 3 and the p+ type contact region 5 are provided on the p type base region 2. The gate electrode 10 faces the p type base region 2 via the gate insulating layer 11 in the X direction. The gate electrode 10 is electrically connected to the gate pad 24 through the gate wiring 25 and the third contact 33 shown in FIG. 4.

The p type base region 2 is provided in multiple numbers in the X direction. On one p type base region 2, the n+ type source region 3 and the p+ type contact region 5 are alternately arranged in the X direction. On another p type base region 2, only the p+ type contact region 5 is provided, and the n+ type source region 3 is not provided. For example, as shown in FIG. 2, the p type base region 2 with only the n+ type source region 3 provided on the upper part and the p type base region 2 with only the p+ type contact region 5 provided on the upper part are alternately arranged in the X direction.

The upper electrode 22 is provided on the p type base region 2, the n+ type source region 3, and the p+ type contact region 5 via the first contact 31. The upper electrode 22 is electrically connected to the p type base region 2, the n+ type source region 3, and the p+ type contact region 5 via the first contact 31. The insulating layer 15 is provided between the gate electrode 10 and the upper electrode 22. The gate electrode 10 and the upper electrode 22 are electrically separated from each other by the insulating layer 15.

As shown in FIG. 3, the p type guard ring region 4 is provided above the second region 1b. The p type guard ring region 4 is located around the plurality of p type base regions 2 along the X-Y plane. The guard ring electrode 23 is provided on the p type guard ring region 4 via the second contact 32. The guard ring electrode 23 is located around the upper electrode 22 along the X-Y plane. The guard ring electrode 23 is electrically connected to the p type guard ring region 4 via the second contact 32.

A plurality of p type guard ring regions 4 are provided separately from each other in the direction from the first region 1a to the second region 1b. A plurality of the guard ring electrodes 23 are also provided separated from each other in the direction from the first region 1a to the second region 1b. The plurality of guard ring electrodes 23 are provided on the plurality of p type guard ring regions 4 via a plurality of second contacts 32, respectively.

Above the second region 1b, the upper surface of the n− type semiconductor region 1 is covered by the insulating layer 15. The thickness of the insulating layer 15 provided above the second region 1b in the Z direction is greater than the thickness of the insulating layer 15 provided above the first region 1a in the Z direction. The second contact 32 is aligned with the insulating layer 15 in the direction from the first region 1a to the second region 1b. A part of the insulating layer 15 is located between a part of the p type guard ring region 4 and a part of the guard ring electrode 23.

As shown in FIG. 4, no p type semiconductor regions such as the p type base region 2 or the p type guard ring region 4 are provided above the third region 1c. Above the third region 1c, the upper surface of the n− type semiconductor region 1 is covered by the insulating layer 15. The thickness of the insulating layer 15 provided above the third region 1c in the Z direction is greater than the thickness of the insulating layer 15 provided above the first region 1a in the Z direction.

Furthermore, above the third region 1c, the gate wiring 25 is provided in the insulating layer 15. The gate wiring 25 is electrically connected to the plurality of gate electrodes 10. The gate pad 24 is located above the gate wiring 25 and is electrically connected to the gate wiring 25 via the third contact 33.

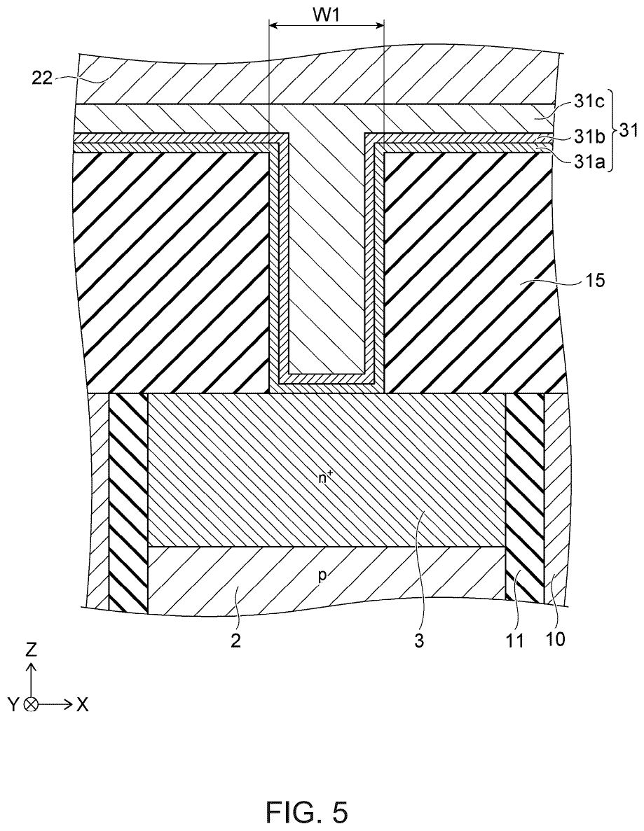

FIG. 5 is an enlarged cross-sectional view of a part of FIG. 2. As shown in FIG. 5, the first contact 31 includes a first titanium-containing layer 31a, a first titanium nitride-containing layer 31b, and a first tungsten-containing layer 31c.

The first titanium-containing layer 31a contains titanium. The first titanium-containing layer 31a is provided along the upper surface of the n+ type source region 3, the upper surface of the p+ type contact region 5 (not shown in FIG. 5), and the surface of the insulating layer 15. For example, the first titanium-containing layer 31a is in contact with the upper surface of the n+ type source region 3 and the upper surface of the p+ type contact region 5.

The first titanium nitride-containing layer 31b contains titanium nitride and is provided on the first titanium-containing layer 31a. The thickness of each part of the first titanium nitride-containing layer 31b is substantially uniform, and the first titanium nitride-containing layer 31b is provided along the first titanium-containing layer 31a.

The first tungsten-containing layer 31c contains tungsten and is provided on the first titanium nitride-containing layer 31b. The first tungsten-containing layer 31c is thicker than the first titanium-containing layer 31a and the first titanium nitride-containing layer 31b and fills the opening formed in the insulating layer 15. The first tungsten-containing layer 31c is in contact with the upper electrode 22.

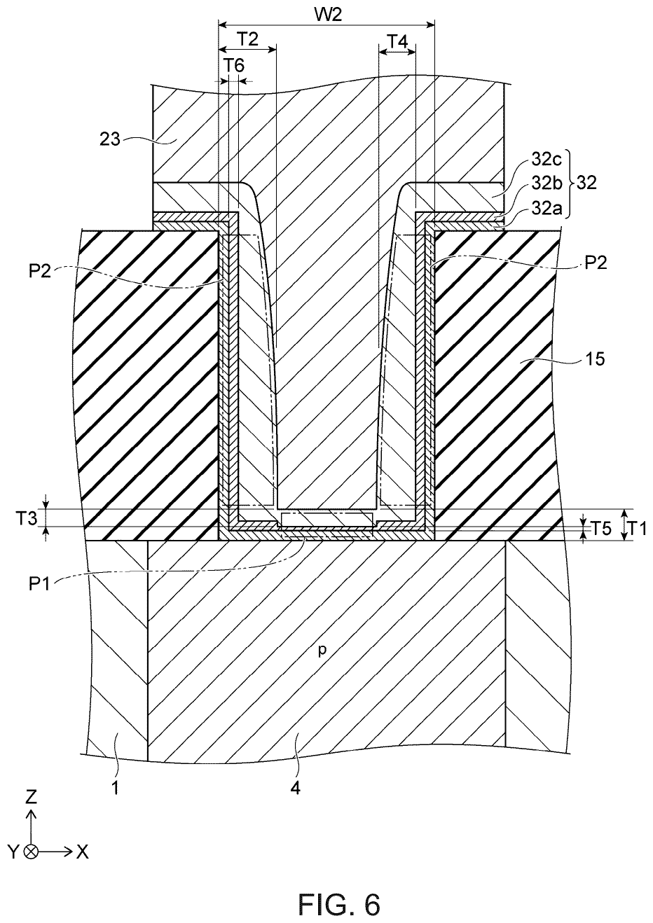

FIG. 6 is an enlarged cross-sectional view of a part of FIG. 3. As shown in FIG. 6, the second contact 32 includes a second titanium-containing layer 32a, a second titanium nitride-containing layer 32b, and a second tungsten-containing layer 32c.

The second titanium-containing layer 32a contains titanium. The second titanium-containing layer 32a is provided along the upper surface of the p type guard ring region 4 and the surface of the insulating layer 15. The second titanium-containing layer 32a is in contact with the upper surface of the p type guard ring region 4.

The second titanium nitride-containing layer 32b contains titanium nitride and is provided on the second titanium-containing layer 32a. The second titanium nitride-containing layer 32b is provided along the second titanium-containing layer 32a.

The second tungsten-containing layer 32c contains tungsten and is provided on the second titanium nitride-containing layer 32b. The second tungsten-containing layer 32c is thicker than the second titanium-containing layer 32a and the second titanium nitride-containing layer 32b. The second tungsten-containing layer 32c is in contact with the guard ring electrode 23.

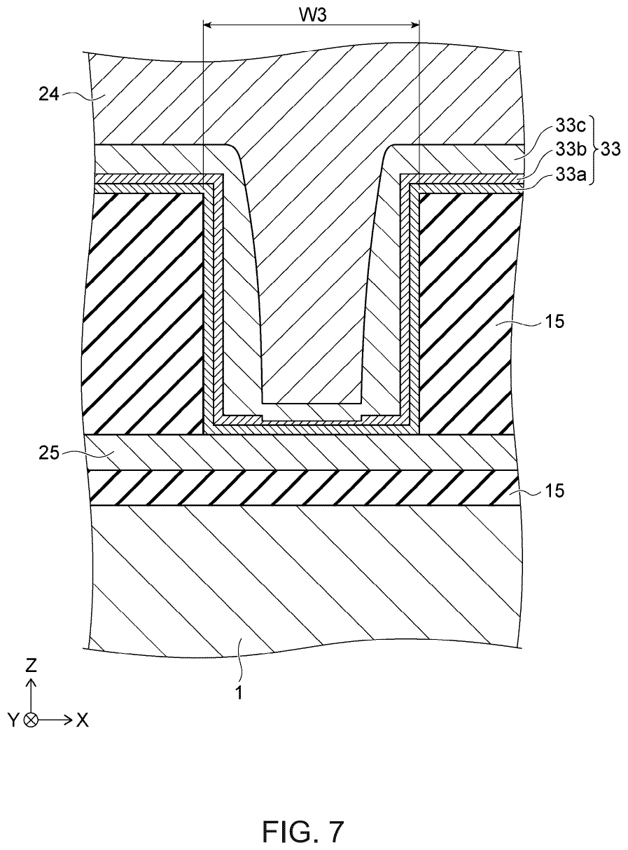

FIG. 7 is an enlarged cross-sectional view of a part of FIG. 4. As shown in FIG. 7, the third contact 33 includes a third titanium-containing layer 33a, a third titanium nitride-containing layer 33b, and a third tungsten-containing layer 33c.

The third titanium-containing layer 33a contains titanium. The third titanium-containing layer 33a is provided along the upper surface of the gate wiring 25 and the surface of the insulating layer 15. For example, the third titanium-containing layer 33a is in contact with the upper surface of the gate wiring 25.

The third titanium nitride-containing layer 33b contains titanium nitride and is provided on the third titanium-containing layer 33a. The third titanium nitride-containing layer 33b is provided along the third titanium-containing layer 33a.

The third tungsten-containing layer 33c contains tungsten and is provided on the third titanium nitride-containing layer 33b. The third tungsten-containing layer 33c is thicker than the third titanium-containing layer 33a and the third titanium nitride-containing layer 33b. The third tungsten-containing layer 33c is in contact with the gate pad 24.

As described above, the bottom of the first contact 31 is in contact with the n+ type source region 3 and the p+ type contact region 5, the bottom of the second contact 32 in contact with the p type guard ring region 4, and the bottom of the third contact 33 in contact with the gate wiring 25. The width W2 of the bottom of the second contact 32 and the width W3 of the bottom of the third contact 33 are wider than the width W1 of the bottom of the first contact 31. The “width” refers to the length in one direction perpendicular to the Z direction, which corresponds to the length in the X direction in the illustrated example. For example, the width W2 and the width W3 are greater than 1.4 times the width W1 and less than or equal to twice the width W1.

The third contact 33 may have the same structure as the second contact 32. For example, the specific structure of the second contact 32 described below can also be applied to the third contact 33.

As shown in FIG. 6, the second contact 32 may include a first portion P1 and a second portion P2. The first portion P1 is in contact with the p type guard ring region 4 and is located between the p type guard ring region 4 and the guard ring electrode 23 in the Z direction. The second portion P2 is in contact with the insulating layer 15 and is located between the insulating layer 15 and the guard ring electrode 23 in the X direction. The maximum thickness T2 of the second portion P2 in the X direction is greater than the maximum thickness T1 of the first portion P1 in the Z direction.

For example, the maximum thickness T4 of the second tungsten-containing layer 32c in the X direction included in the second portion P2 is greater than the maximum thickness T3 of the second tungsten-containing layer 32c in the Z direction included in the first portion P1. In addition, as depicted in FIG. 6, the thickness T5 of the second titanium nitride-containing layer 32b in the Z direction included in the first portion P1 is smaller than the thickness T6 of the second titanium nitride-containing layer 32b in the X direction included in the second portion P2.

An example of the materials of each component is described. The n− type semiconductor region 1, the p type base region 2, the n+ type source region 3, the p type guard ring region 4, the p+ type contact region 5, the p+ type collector region 6, and the n type buffer region 7 include silicon, silicon carbide, gallium nitride, or gallium arsenide as semiconductor materials. When silicon is used as the semiconductor material, arsenic, phosphorus, or antimony can be used as the n type impurity. Boron can be used as the p type impurity. The gate electrode 10 and the gate wiring 25 include conductive materials such as polysilicon. The gate insulating layer 11 and the insulating layer 15 include insulating materials such as silicon oxide, silicon nitride, or silicon oxynitride. The lower electrode 21, the upper electrode 22, the guard ring electrode 23, and the gate pad 24 include metal materials such as aluminum or copper.

The first titanium-containing layer 31a, the second titanium-containing layer 32a, and the third titanium-containing layer 33a may be composed of pure titanium or may contain metals other than titanium. For example, the portion of the first titanium-containing layer 31a in contact with the n+ type source region 3 or the p+ type contact region 5 may include titanium silicide formed by the reaction of titanium and silicon. The portion of the second titanium-containing layer 32a in contact with the p type guard ring region 4 may include titanium silicide. The first titanium nitride-containing layer 31b, the second titanium nitride-containing layer 32b, and the third titanium nitride-containing layer 33b may be composed of pure titanium nitride or may contain metal compounds other than titanium nitride. The first tungsten-containing layer 31c, the second tungsten-containing layer 32c, and the third tungsten-containing layer 33c may be composed of pure tungsten or may contain metals other than tungsten. Preferably, the first titanium nitride-containing layer 31b, the second titanium nitride-containing layer 32b, and the third titanium nitride-containing layer 33b are composed substantially of titanium nitride only, and the first tungsten-containing layer 31c, the second tungsten-containing layer 32c, and the third tungsten-containing layer 33c are composed substantially of tungsten only.

The operation of the semiconductor device 100 will be described. When the semiconductor device 100 is turned on, a positive voltage is applied to the lower electrode 21 with respect to the upper electrode 22, and a voltage above the threshold is applied to the gate electrode 10. A channel (inversion layer) is formed in the p type base region 2, and electrons are injected from the n+ type source region 3 into the n− type semiconductor region 1 through the channel. Holes are injected from the p+ type collector region 6 into the n− type semiconductor region 1. Conductivity modulation occurs in the n− type semiconductor region 1, reducing the electrical resistance of the semiconductor device 100. Subsequently, when the voltage applied to the gate electrode 10 becomes lower than the threshold, the channel in the p type base region 2 disappears, and the semiconductor device 100 turns off.

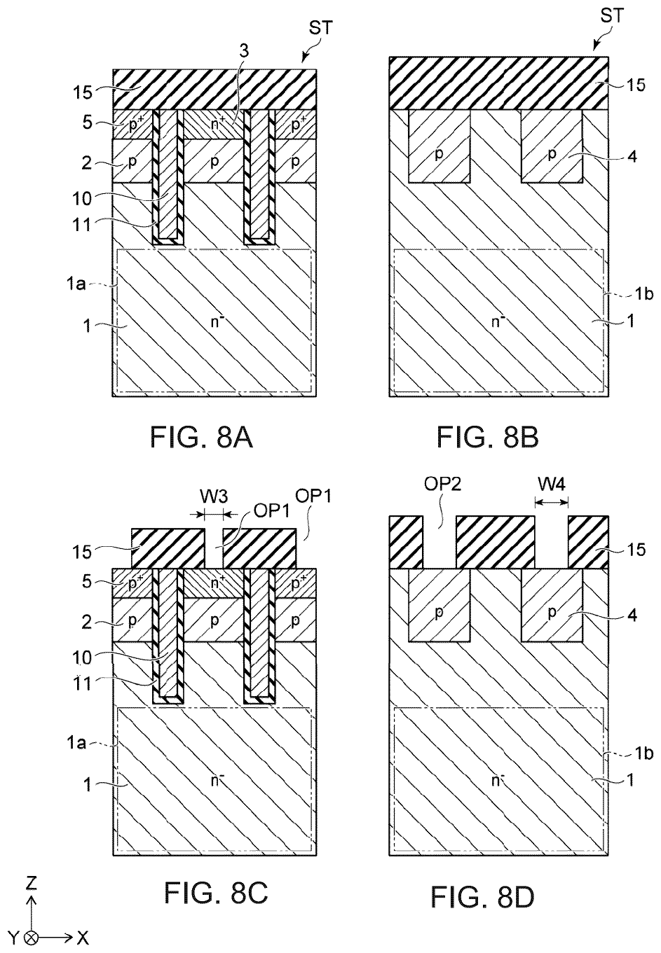

FIGS. 8A to 10D are cross-sectional views showing a method of manufacturing a semiconductor device according to an embodiment. FIGS. 8A, 8C, 9A, 9C, 10A, and 10C show the manufacturing process along line II-II of FIG. 1. FIGS. 8B, 8D, 9B, 9D, 10B, and 10D show the manufacturing process along line III-III of FIG. 1.

First, a semiconductor substrate including the n− type semiconductor region 1 is prepared. By a known method, the p type base region 2, n+ type source region 3, p type guard ring region 4, p+ type contact region 5, gate electrode 10, gate insulating layer 11, and insulating layer 15 are formed on the upper part of the n− type semiconductor region 1. This results in the structure ST shown in FIGS. 8A and 8B. The n− type semiconductor region 1 includes the first region 1a and the second region 1b. The direction from the first region 1a to the p type base region 2 is parallel to the Z direction.

By photolithography and reactive ion etching (RIE), the first opening OP1 and the second opening OP2 are formed in the insulating layer 15 as shown in FIGS. 8C and 8D. The first opening OP1 is formed over the n+ type source region 3 and the p+ type contact region 5. The second opening OP2 is formed over the p type guard ring region 4. The width W4 of the second opening OP2 is wider than the width W3 of the first opening OP1.

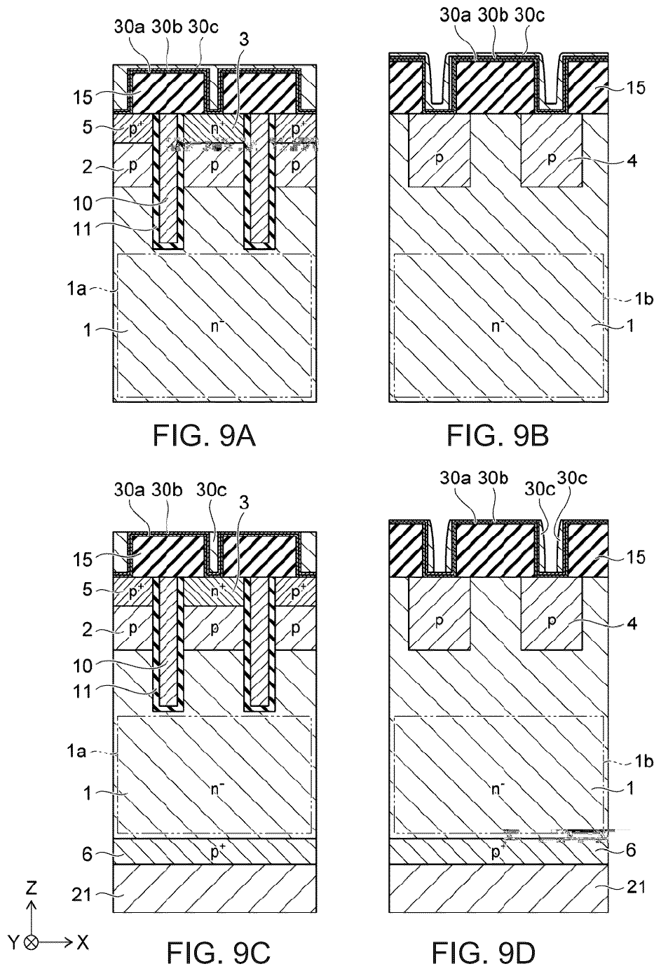

By chemical vapor deposition (CVD), a titanium-containing layer 30a is formed along the inner surfaces of the first opening OP1 and the second opening OP2. By CVD, a titanium nitride-containing layer 30b is formed on the titanium-containing layer 30a. By CVD, a tungsten-containing layer 30c is formed on the titanium nitride-containing layer 30b. As shown in FIGS. 9A and 9B, the first opening OP1 is filled with the tungsten-containing layer 30c. The second opening OP2 is not filled with the tungsten-containing layer 30c because it is wider than the first opening OP1.

The upper part of the tungsten-containing layer 30c is removed by RIE, and the upper surface of the tungsten-containing layer 30c is recessed. As shown in FIG. 9C, the tungsten-containing layer 30c formed on the insulating layer 15 above the first region 1a is removed, leaving the first opening OP1 filled with the tungsten-containing layer 30c. As shown in FIG. 9D, the tungsten-containing layer 30c formed on the insulating layer 15 and the bottom of the second opening OP2 above the second region 1b is removed. Additionally, a part of the titanium nitride-containing layer 30b at the bottom of the second opening OP2 is removed. As a result, the thickness of the titanium nitride-containing layer 30b formed at the bottom of the second opening OP2 becomes smaller than the thickness of the titanium nitride-containing layer 30b formed at the bottom of the first opening OP1.

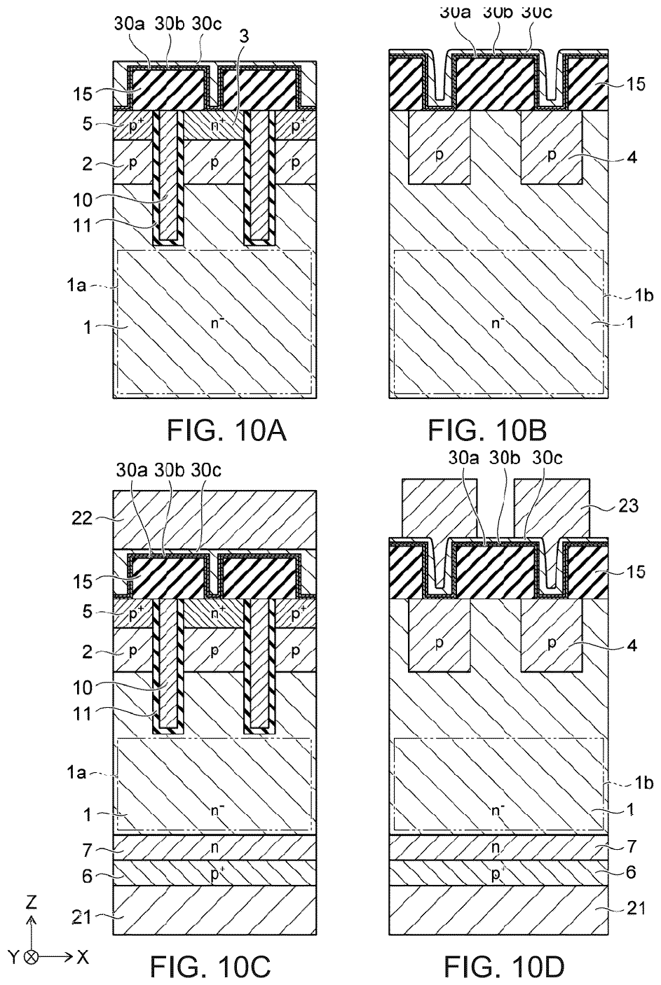

By CVD, the tungsten-containing layer 30c is formed again. As a result, the thickness of the tungsten-containing layer 30c increases as shown in FIGS. 10A and 10B. Additionally, the tungsten-containing layer 30c is formed again at the bottom of the second opening OP2 where the titanium nitride-containing layer 30b was exposed.

By sputtering, a metal layer is formed on the tungsten-containing layer 30c, and then by RIE, the metal layer, tungsten-containing layer 30c, titanium nitride-containing layer 30b, and titanium-containing layer 30a are patterned. The titanium-containing layer 30a, titanium nitride-containing layer 30b, and tungsten-containing layer 30c formed above the second region 1b are separated from those formed above the first region 1a. Additionally, the titanium-containing layer 30a, titanium nitride-containing layer 30b, and tungsten-containing layer 30c above the second region 1b are separated into multiple parts. This forms the first contact 31 and the second contact 32. Additionally, the upper electrode 22, guard ring electrode 23, and gate pad 24 are formed by patterning the metal layer.

The lower surface of the n− type semiconductor region 1 is ground until the n− type semiconductor region 1 reaches a predetermined thickness. An n type impurity is ion-implanted into the ground lower surface of the n− type semiconductor region 1 to form the n type buffer region 7. A p type impurity is ion-implanted into the lower surface of the n type buffer region 7 to form the p+ type collector region 6. As shown in FIGS. 10C and 10D, the lower electrode 21 is formed by sputtering in contact with the p+ type collector region 6. Thus, the semiconductor device 100 according to the embodiment is manufactured.

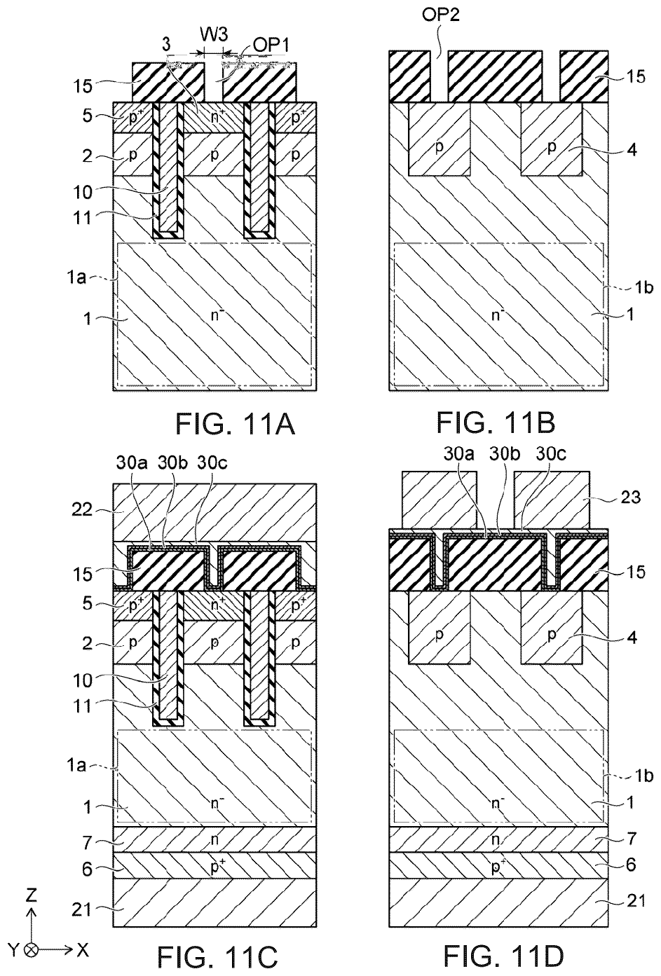

FIGS. 11A to 11D are cross-sectional views showing a manufacturing method according to a first reference example. In the manufacturing method according to the first reference example, as shown in FIGS. 11A and 11B, the width of the first opening OP1 and the width of the second opening OP2 are the same. As a result, as shown in FIGS. 11C and 11D, the width of the first contact 31 and the width of the second contact 32 can be the same.

In the manufacturing method according to the first reference example, the thickness of the insulating layer 15 formed above the first region 1a is different from the thickness of the insulating layer 15 formed above the second region 1b. Therefore, the focal position of the photolithography when forming the first opening OP1 above the first region 1a is different from the focal position of the photolithography when forming the second opening OP2 above the second region 1b. When the width of the second opening OP2 and the width of the first opening OP1 are made the same, it becomes difficult to secure the focus margin. The focus margin is the margin that allows the pattern dimensions to be within the allowable range when the focus deviates from the design position. As a result, the yield of the semiconductor device may decrease.

To address this issue, in the embodiment of the present invention, as shown in FIGS. 8C and 8D, the width of the second opening OP2 is wider than the width of the first opening OP1. Therefore, compared to the first reference example, the formation of the second opening OP2 is easier. As a result, the yield of the semiconductor device can be improved. Additionally, when the width of the second opening OP2 is wider than the width of the first opening OP1, as shown in FIGS. 2, 3, 5, and 6, the width of the second contact 32 can be made wider than the width of the first contact 31. As a result, the contact resistance between the p type guard ring region 4 and the second contact 32 can be reduced, and the p type guard ring region 4 and the guard ring electrode 23 can be more reliably electrically connected. For example, the spread of the depletion layer in the terminal region of the semiconductor device 100 can be more stabilized.

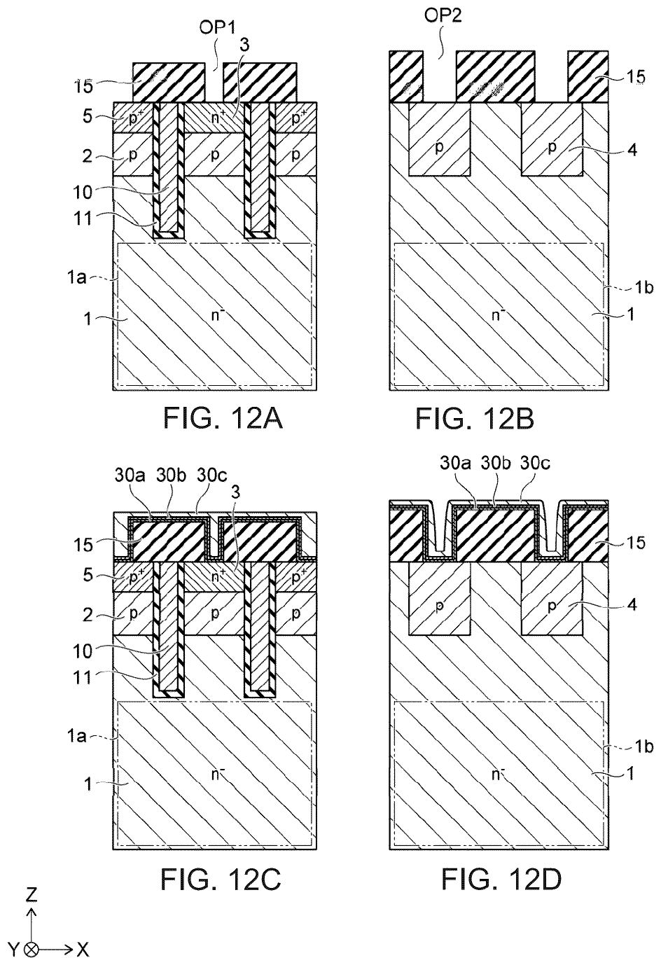

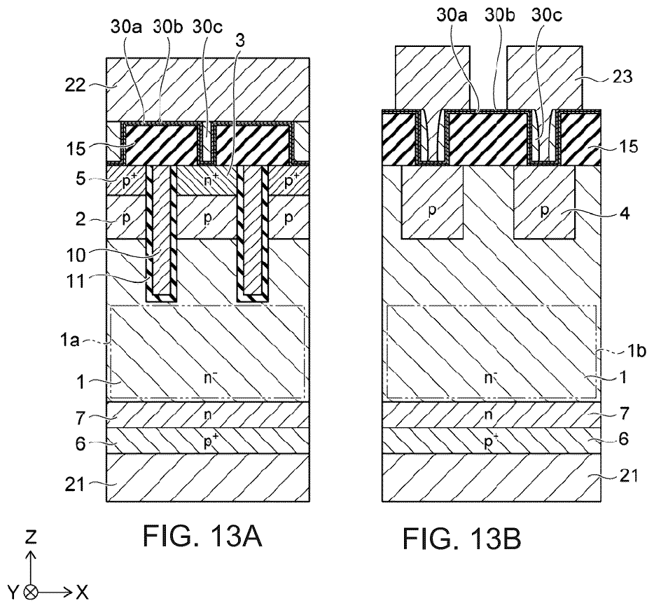

FIGS. 12A to 12B, FIGS. 13A, and FIG. 13B are cross-sectional views showing a manufacturing method according to a second reference example. In the manufacturing method according to the second reference example, as shown in FIGS. 12A and 12B, the width of the second opening OP2 is wider than the width of the first opening OP1. FIGS. 12C and 12D show the state where the titanium-containing layer 30a, titanium nitride-containing layer 30b, and tungsten-containing layer 30c are formed. The first opening OP1 is filled with the tungsten-containing layer 30c. On the other hand, the second opening OP2 is not completely filled with the tungsten-containing layer 30c.

In this state, when RIE is performed, the tungsten-containing layer 30c formed at the bottom of the second opening OP2 is removed, and the titanium nitride-containing layer 30b is exposed at the bottom of the second opening OP2. A part of the exposed titanium nitride-containing layer 30b is removed by RIE. As a result, the thickness of the part of the titanium nitride-containing layer 30b becomes smaller.

FIGS. 13A and 13B show the state where the upper electrode 22 is formed thereafter. At the bottom of the second opening OP2, the tungsten-containing layer 30c is removed. Therefore, between the p type guard ring region 4 and the upper electrode 22, there is no tungsten-containing layer 30c, and only the titanium-containing layer 30a and the titanium nitride-containing layer 30b are present. Additionally, at the bottom of the second opening OP2, the thickness of the titanium nitride-containing layer 30b is smaller than the thickness of the other parts of the titanium nitride-containing layer 30b.

The titanium-containing layer 30a, titanium nitride-containing layer 30b, and tungsten-containing layer 30c function as barrier layers to suppress the reaction between the semiconductor material and the metal material of the electrode. When the semiconductor device manufactured by the manufacturing method according to the second reference example is used, there is no tungsten-containing layer 30c between the p type guard ring region 4 and the guard ring electrode 23, and the thickness of the titanium nitride-containing layer 30b is also small. Therefore, a reaction between the semiconductor material of the p type guard ring region 4 and the metal material of the guard ring electrode 23 may occur. For example, the metal material of the guard ring electrode 23 (especially aluminum) may diffuse into the p type guard ring region 4, causing a phenomenon called alloy spike.

To address this issue, in the embodiment of the present invention, as shown in FIGS. 9C and 9D, after etching the tungsten-containing layer 30c, the tungsten-containing layer 30c is formed again as shown in FIGS. 10A and 10B. As a result, the tungsten-containing layer 30c is again placed at the bottom of the second opening OP2. Additionally, the thickness of the tungsten-containing layer 30c formed the second time is smaller than the thickness of the tungsten-containing layer 30c formed the first time. The layer containing tungsten has greater stress compared to other layers. By forming the second tungsten-containing layer 30c thinner, the stress generated in the semiconductor device 100 can be reduced, and the warpage of the semiconductor device 100 can be reduced.

According to the manufacturing method of the embodiment, in the second contact 32, a three-layer structure of the second titanium-containing layer 32a, the second titanium nitride-containing layer 32b, and the second tungsten-containing layer 32c is formed between the p type guard ring region 4 and the guard ring electrode 23. Therefore, compared to the semiconductor device according to the second reference example shown in FIG. 13B, the reaction between the semiconductor material of the p type guard ring region 4 and the metal material of the guard ring electrode 23 can be suppressed. In addition, the destruction of the semiconductor device 100 due to alloy spike is less likely to occur, and the reliability of the semiconductor device 100 can be improved.

According to the embodiment, the contact resistance between the p type guard ring region 4 and the guard ring electrode 23 can be reduced while suppressing the reaction between the semiconductor material of the p type guard ring region 4 and the metal material of the guard ring electrode 23.

In the semiconductor device 100, a part of the guard ring electrode 23 is formed inside the second opening OP2. That is, as shown in FIG. 6, a part of the guard ring electrode 23 is located between a part of the second contact 32 and another part of the second contact 32 in the X direction. The guard ring electrode 23 includes metals such as aluminum and copper as described above. The electrical resistivity of these metals is lower than the electrical resistivity of tungsten. By positioning a part of the guard ring electrode 23 between a part of the second contact 32 and another part of the second contact 32, the electrical resistance between the p type guard ring region 4 and the guard ring electrode 23 can be reduced.

Additionally, as shown in FIG. 6, the second contact 32 includes the first portion P1 and the second portion P2, and the maximum thickness T1 of the first portion P1 is smaller than the maximum thickness T2 of the second portion P2. According to this structure, the lower end of the guard ring electrode 23 is positioned closer to the p type guard ring region 4 compared to when the maximum thickness T2 is greater than the maximum thickness T1. Therefore, the electrical resistance between the p type guard ring region 4 and the guard ring electrode 23 can be further reduced.

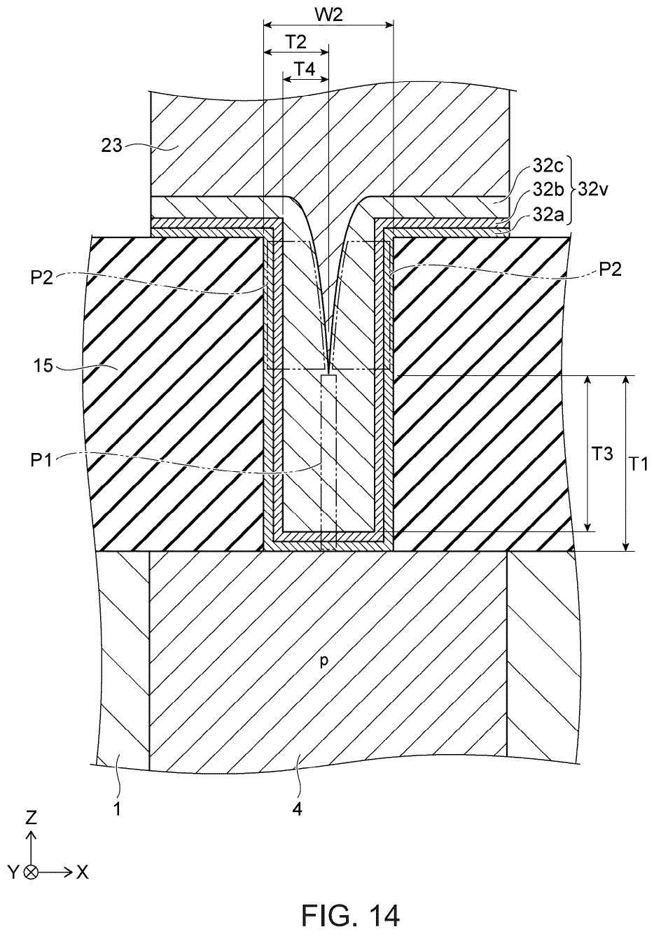

FIG. 14 is a cross-sectional view showing another example of the second contact. As shown in FIG. 14, the width of the second contact 32v may be narrower than that of the second contact 32 in the example shown in FIG. 6. However, even in this case, the width W2 of the bottom of the second contact 32v is wider than the width W1 of the bottom of the first contact 31 (shown in FIG. 5). For example, the width W2 is between 1.1 and 1.4 times the width W1.

In the structure shown in FIG. 14, the maximum thickness T1 of the first portion P1 in the Z direction of the second contact 32v is greater than the maximum thickness T2 of the second portion P2 in the X direction. The maximum thickness T3 of the second tungsten-containing layer 32c in the Z direction included in the first portion P1 is greater than the maximum thickness T4 of the second tungsten-containing layer 32c in the X direction included in the second portion P2.

In the structure shown in FIG. 14, a part of the guard ring electrode 23 is located between a part of the second contact 32v and another part of the second contact 32v in the X direction. Therefore, the electrical resistance between the p type guard ring region 4 and the guard ring electrode 23 can be reduced.

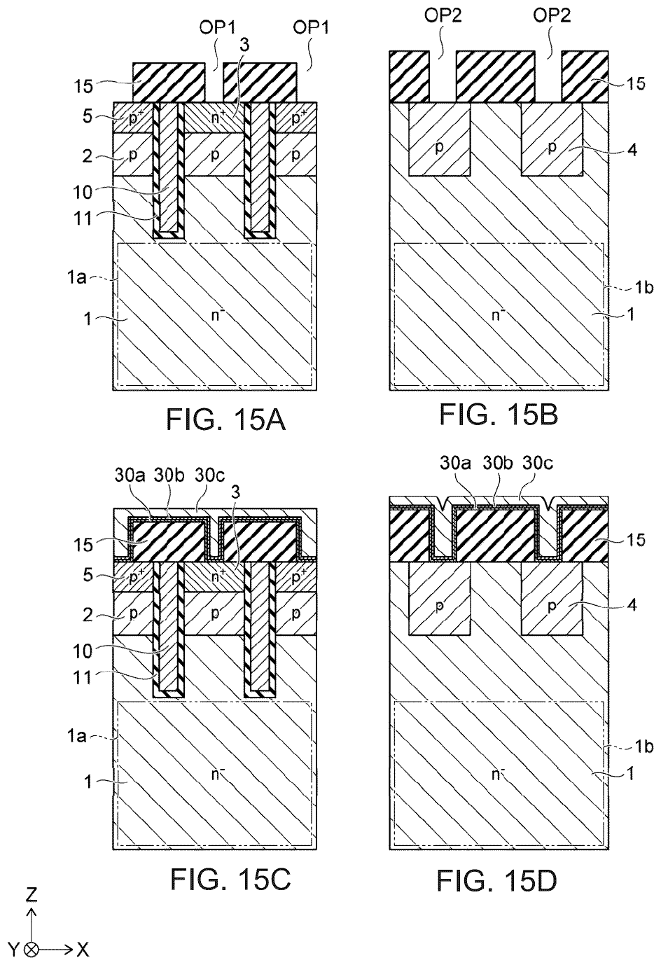

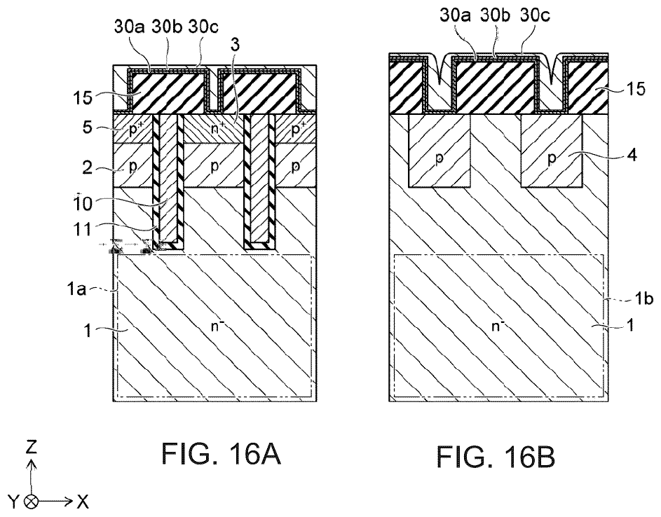

FIGS. 15A to 15D, and FIGS. 16A and 16B are cross-sectional views showing a method of manufacturing a semiconductor device according to an embodiment. To form the second contact 32v shown in FIG. 14, first, the same steps as shown in FIGS. 8A to 8D are performed, and the first opening OP1 and the second opening OP2 are formed as shown in FIGS. 15A and 15B. The width of the second opening OP2 is narrower than the width of the second opening OP2 shown in FIG. 8D. Next, the titanium-containing layer 30a, titanium nitride-containing layer 30b, and tungsten-containing layer 30c are formed. At this time, as shown in FIGS. 15C and 15D, the second opening OP2 is filled with the tungsten-containing layer 30c except for the upper part.

Then, the upper part of the tungsten-containing layer 30c is etched so that the tungsten-containing layer 30c formed at the bottom of the second opening OP2 remains. As a result, as shown in FIGS. 16A and 16B, the upper surface of the tungsten-containing layer 30c is flattened above the first region 1a while the tungsten-containing layer 30c remains at the bottom of the second opening OP2. Subsequently, the upper electrode 22, guard ring electrode 23, gate pad 24, and lower electrode 21 are formed, thereby manufacturing the semiconductor device 100 with the second contact 32v shown in FIG. 14.

Even when the second contact 32v is used, the contact resistance between the p type guard ring region 4 and the guard ring electrode 23 can be reduced while suppressing the reaction between the semiconductor material of the p type guard ring region 4 and the metal material of the guard ring electrode 23, as in the above-described embodiment.

The width W3 of the third contact 33 may also be formed narrower than the example shown in FIG. 7. By doing so, the third contact 33 can be formed to have the same structure as the second contact 32v.

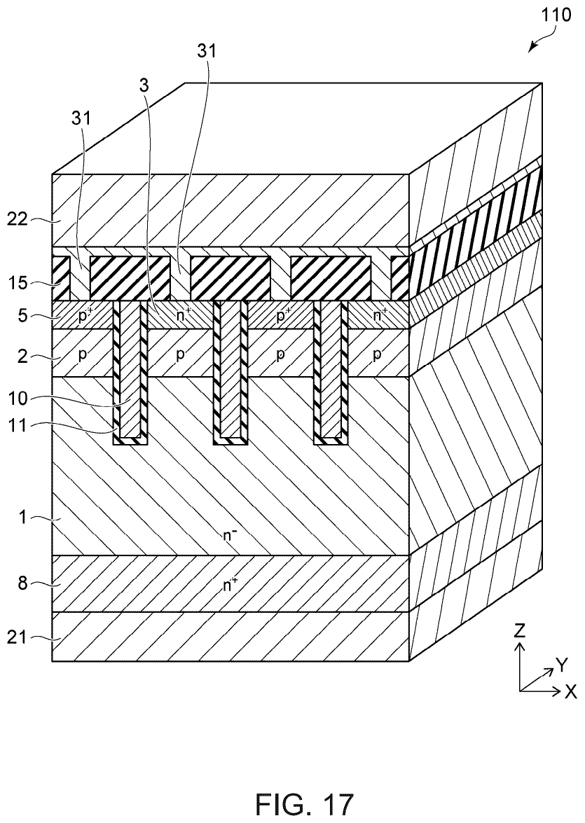

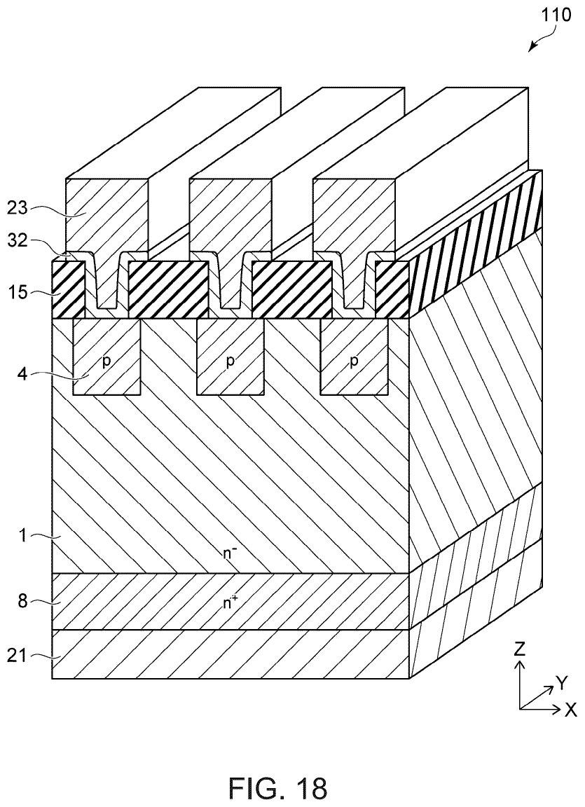

FIGS. 17 and 18 are perspective cross-sectional views showing a part of a semiconductor device according to a modified example of the embodiment. The embodiment of the present invention can also be applied to MOSFETs. The semiconductor device 110 according to the modified example shown in FIGS. 17 and 18 is a MOSFET. The semiconductor device 110 differs from the semiconductor device 100 in that it includes an n+ type drain region 8 instead of the p+ type collector region 6 and the n type buffer region 7.

The n+ type drain region 8 is provided on the lower electrode 21 and is electrically connected to the lower electrode 21. The n− type semiconductor region 1 is provided on the n+ type drain region 8. The n type impurity concentration in the n− type semiconductor region 1 is lower than the n type impurity concentration in the n+ type drain region 8.

In the semiconductor device 110, the second contact 32 including the second tungsten-containing layer 32c is also provided, thereby reducing the contact resistance between the p type guard ring region 4 and the guard ring electrode 23 while suppressing the reaction between the semiconductor material of the p type guard ring region 4 and the metal material of the guard ring electrode 23.

The relative impurity concentration levels between the semiconductor regions in each embodiment described above can be confirmed using, for example, a scanning capacitance microscope (SCM). The carrier concentration in each semiconductor region can be considered equal to the activated impurity concentration in each semiconductor region. Therefore, the relative carrier concentration levels between the semiconductor regions can also be confirmed using SCM. The impurity concentration in each semiconductor region can be measured using, for example, secondary ion mass spectrometry (SIMS).

While several embodiments of the present invention have been illustrated above, these embodiments are presented as examples and are not intended to limit the scope of the invention. These novel embodiments can be implemented in various other forms, and various omissions, substitutions, and changes can be made without departing from the gist of the invention. These embodiments and their modifications are included in the scope and gist of the invention and are included in the scope of the invention described in the claims and their equivalents. Additionally, the above-described embodiments can be implemented in combination with each other.

What is claimed is:

1. A semiconductor device comprising:
a first electrode;
a first semiconductor region of a first conductivity type, provided above the first electrode in a first direction and including a first region and a second region positioned around the first region in a first plane perpendicular to the first direction;
a second semiconductor region of a second conductivity type provided on the first region;
a third semiconductor region of the first conductivity type provided on the second semiconductor region;
a gate electrode facing the second semiconductor region via a gate insulating layer in a second direction perpendicular to the first direction;
a fourth semiconductor region of the second conductivity type provided on the second region and spaced apart from the second semiconductor region;
a second electrode provided on the second semiconductor region and the third semiconductor region via a first contact including a first titanium-containing layer, a first titanium nitride-containing layer provided on the first titanium-containing layer, and a first tungsten-containing layer provided on the first titanium nitride-containing layer; and
a third electrode provided on the fourth semiconductor region via a second contact including a second titanium-containing layer, a second titanium nitride-containing layer that is provided on the second titanium-containing layer, and a second tungsten-containing layer that is provided on the second titanium nitride-containing layer and in direct contact with a lowermost portion of the third electrode.

2. The semiconductor device according to claim 1, wherein the second semiconductor region includes a plurality of semiconductor regions of the second conductivity in the second direction, and the fourth semiconductor region is positioned around the plurality of spaced-apart semiconductor regions of the second conductivity in a second plane perpendicular to the first direction.

3. The semiconductor device according to claim 2, wherein the fourth semiconductor region includes a plurality of semiconductor regions of the second conductivity that are spaced apart from each other in a direction from the first region to the second region, and the third electrode includes a plurality of electrodes provided respectively on the plurality of semiconductor regions of the fourth semiconductor region via a plurality of contacts that include the second contact.

4. The semiconductor device according to claim 1, wherein a length in the second direction of a portion of the second contact in contact with the fourth semiconductor region is greater than a length in the second direction of a portion of the first contact in contact with the third semiconductor region.

5. The semiconductor device according to claim 1, further comprising:
an insulating layer provided alongside the second contact in the second direction, wherein the second contact includes:
a first portion positioned between the fourth semiconductor region and the third electrode in the first direction; and
a second portion positioned between the insulating layer and the third electrode in the second direction.

6. The semiconductor device according to claim 5, wherein a maximum thickness in the first direction of the first portion is smaller than a maximum thickness in the second direction of the second portion.

7. The semiconductor device according to claim 6, wherein a maximum thickness in the first direction of the second tungsten-containing layer included in the second portion is larger than a maximum thickness in the first direction of the second tungsten-containing layer included in the first portion.

8. The semiconductor device according to claim 5, wherein a maximum thickness in the first direction of the first portion is larger than a maximum thickness in the second direction of the second portion.

9. The semiconductor device according to claim 8, wherein a maximum thickness in the first direction of the second titanium nitride-containing layer included in the first portion is smaller than a maximum thickness in the first direction of the first titanium nitride-containing layer.

10. A method for manufacturing a semiconductor device, comprising:
forming a first semiconductor region of a first conductivity type above a first electrode in a first direction, the first semiconductor region including a first region and a second region positioned around the first region in a first plane that is perpendicular to the first direction;
forming a second semiconductor region of a second conductivity type on the first region;
forming a third semiconductor region of the first conductivity type on the second semiconductor region;
forming a gate electrode facing the second semiconductor region via a gate insulating layer in a second direction perpendicular to the first direction;
forming a fourth semiconductor region of the second conductivity type on the second region and spaced apart from the second semiconductor region;
forming an insulating layer having a first opening positioned on the third semiconductor region and a second opening positioned on the fourth semiconductor region;
forming a titanium-containing layer along side and bottom portions of the first and second openings;
forming a titanium nitride-containing layer on the titanium-containing layer;
forming a tungsten-containing layer on the titanium nitride-containing layer;
etching the tungsten-containing layer so that the tungsten-containing layer is removed completely from the bottom portion of the second opening to expose the titanium nitride-containing layer; and
forming a tungsten-containing layer again after etching the tungsten-containing layer.

11. The method of claim 10, wherein a width of the second opening is greater than a width of the first opening.

12. The method of claim 11, wherein the width of the second opening is about 1.4 to 2.0 times the width of the first opening.

13. The method of claim 10, wherein the etching of the tungsten-containing layer also partially etches the exposed portion of the titanium nitride-containing layer.

14. A method for manufacturing a semiconductor device, comprising:
forming a first semiconductor region of a first conductivity type above a first electrode in a first direction, the first semiconductor region including a first region and a second region positioned around the first region in a first plane that is perpendicular to the first direction;
forming a second semiconductor region of a second conductivity type on the first region;
forming a third semiconductor region of the first conductivity type on the second semiconductor region;
forming a gate electrode facing the second semiconductor region via a gate insulating layer in a second direction perpendicular to the first direction;
forming a fourth semiconductor region of the second conductivity type on the second region and spaced apart from the second semiconductor region;
forming an insulating layer having a first opening positioned on the third semiconductor region and a second opening positioned on the fourth semiconductor region;
forming a titanium-containing layer along side and bottom portions of the first and second openings;
forming a titanium nitride-containing layer on the titanium-containing layer;
forming a tungsten-containing layer on the titanium nitride-containing layer;
etching the upper portion of the tungsten-containing layer to leave the tungsten-containing layer formed at the bottom of the second opening.

15. The method of claim 14, wherein a width of the second opening is greater than a width of the first opening.

16. The method of claim 15, wherein the width of the second opening is about 1.1 to 1.4 times the width of the first opening.
